(19) United States
(12) Patent Application Publication
(10) Pub. No.: US 2024/0413112 A1
(43) Pub. Date: Dec. 12, 2024

(54) INTEGRATED CIRCUIT DEVICE INCLUDING MULTI-LAYER INTERCONNECT PILLAR

(71) Applicant: QUALCOMM Incorporated, San Diego, CA (US)

(72) Inventors: Dongming HE, San Diego, CA (US); Hung-Yuan HSU, Taichung (TW); Yujen CHEN, Taichung (TW)

(21) Appl. No.: 18/330,657

(22) Filed: Jun. 7, 2023

(51) Int. Cl. H01L 23/00

(52) U.S. Cl. CPC H01L 24/13; H01L 24/11; H01L 24/16; H01L 24/32; H01L 24/73; H01L 24/81; H01L 2224/0401; H01L 2224/13147; H01L 2224/16225; H01L 2224/32225; H01L 2224/73204; H01L 2224/81815

(57) ABSTRACT

An integrated device includes a die having a contact pad and a solder cap electrically connected to the contact pad by a multi-layer interconnect pillar. The multi-layer interconnect pillar includes a base reinforcement layer, a cap reinforcement layer, and one or more solder layers disposed between the base reinforcement layer and the cap reinforcement layer.

### FIELD

Various features related to integrated circuit devices.

### BACKGROUND

Electrical connections exist at each level of a system hierarchy. This system hierarchy includes interconnection of devices and/or components at a lowest system level all the way up to system level interconnections at the highest level. For example, interconnect layers can connect different devices/component together on an integrated circuit. As integrated circuits become more complex, more interconnect layers are used to provide the electrical connections between the devices/components. More recently, the number of interconnect levels for circuitry has substantially increased due to the large number of devices/components that are now interconnected in a modern electronic device. The increased number of interconnect levels involves more intricate fabrication processes.

State-of-the-art mobile application devices demand a small form factor, low cost, a tight power budget, and high electrical performance. Increasingly small form factors combined with increasingly complex circuits leads to challenges with interconnecting components of a device. For example, a device can include multiple integrated circuit devices that are interconnected to operate in conjunction with one another. In such devices, smaller integrated circuit devices have less area that can be used to provide electrical interconnects, leading to challenges with forming reliable, densely packed interconnects.

### SUMMARY

Various features related to integrated circuit devices.

One example provides an integrated device that includes a die having a contact pad and a solder cap electrically connected to the contact pad by a multi-layer interconnect pillar. The multi-layer interconnect pillar includes a base reinforcement layer, a cap reinforcement layer, and a solder layer disposed between the base reinforcement layer and the cap reinforcement layer.

Another example provides a device that includes a substrate and a die. The substrate includes an interface and the die includes a contact pad. The device also includes a multi-layer interconnect pillar disposed between the substrate and the die and electrically connected to the contact pad. The multi-layer interconnect pillar includes a base reinforcement layer, a cap reinforcement layer, and a solder layer disposed between the base reinforcement layer and the cap reinforcement layer. A solder cap is electrically connected to the multi-layer interconnect pillar and to the interface.

Another example provides a method that includes forming a base reinforcement layer of a multi-layer interconnect pillar, where the base reinforcement layer is electrically connected to a contact pad of a die. The method also includes forming a first solder layer of the multi-layer interconnect pillar, where the first solder layer is disposed over the base reinforcement layer. The method includes forming a cap reinforcement layer of the multi-layer interconnect pillar, where the cap reinforcement layer is electrically connected to the contact pad by at least the base reinforcement layer and the first solder layer. The method also includes forming a solder cap of the multi-layer interconnect pillar, where the solder cap is disposed over the cap reinforcement layer.

### BRIEF DESCRIPTION OF THE DRAWINGS

Various features, aspects, and advantages may become apparent from the detailed description set forth below when taken in conjunction with the drawings.

FIG. 1A illustrates a side view of a device including one or more multi-layer interconnect pillars according to aspects disclosed herein.

FIG. 1B illustrates a plan view of the device of FIG. 1A.

FIG. 1C illustrates a cross-sectional view of a portion of the device of FIG. 1A.

FIG. 2 illustrates a cross-sectional view of a portion of a device including one or more multi-layer interconnect pillars according to aspects disclosed herein.

FIG. 3A illustrates a cross-sectional view of a portion of a device including one or more multi-layer interconnect pillars according to aspects disclosed herein.

FIG. 3B illustrates a cross-sectional view of a portion of a device including one or more multi-layer interconnect pillars according to aspects disclosed herein.

FIG. 4 (which extends across several pages) illustrates an exemplary sequence for fabricating a device including one or more multi-layer interconnect pillars according to aspects disclosed herein.

FIG. 5 (which extends across several pages) illustrates another exemplary sequence for fabricating a device including one or more multi-layer interconnect pillars according to aspects disclosed herein.

FIG. 6 illustrates an exemplary flow diagram of a method for fabricating a device including one or more multi-layer interconnect pillars according to aspects disclosed herein.

FIG. 7 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

As used herein, the terms “comprise.” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

Improvements in manufacturing technology and demand for lower cost and more capable electronic devices has led to increasing complexity of integrated circuits (ICs). Often, more complex ICs have more complex interconnection schemes to enable interaction between ICs of a device. The number of interconnect levels for circuitry has substantially increased due to the large number of devices that are now interconnected in a state-of-the-art mobile application device.

These interconnections include back-end-of-line (BEOL) interconnect layers, which may refer to the conductive interconnect layers for electrically coupling to front-end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middle-of-line (MOL) interconnect layers, which interconnect to the FEOL active devices of an IC.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

Aspects of the present disclosure are directed to multi-layer interconnect pillars that enable electrical interconnection between two or more devices. The multi-layer interconnect pillars are configured to enable close packing of electrical interconnections (e.g., a small pitch). The multi-layer interconnect pillars include alternating reinforcement layers and solder layers. This arrangement is dimensionally stable (e.g., does not spread to cause short circuits when pitch distance between electrical interconnections is small) and limits stress introduced into the devices due to rigidity of the electrical interconnections.

### Exemplary Device Including Multi-layer Interconnect Pillar(s)

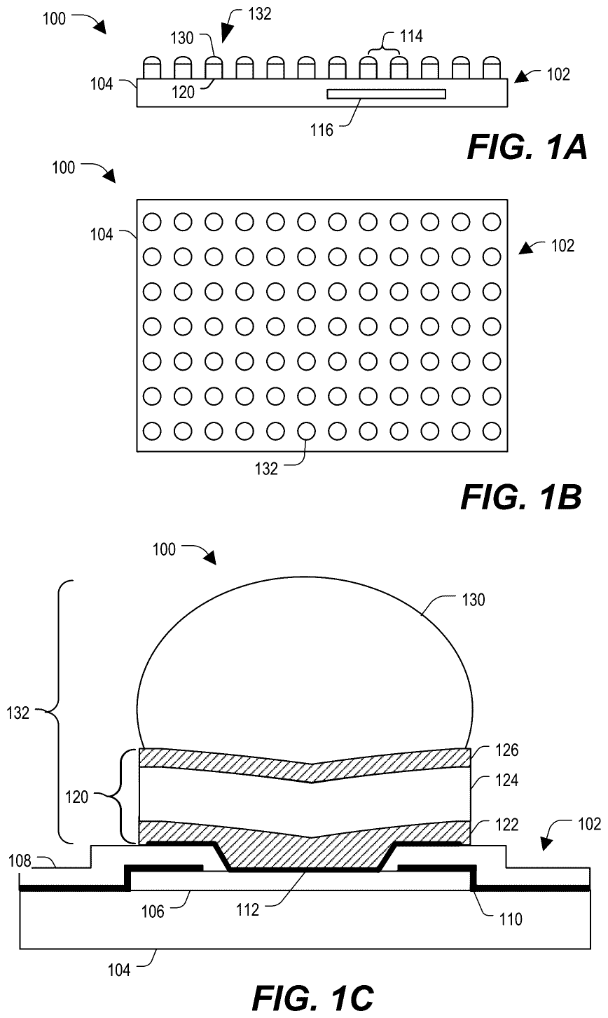

FIGS. 1A-1C illustrate various views of an example of an integrated device 100 according to particular aspects. In particular, FIG. 1A illustrates a side view of the integrated device 100, FIG. 1B illustrates a plan view of the integrated device 100, and FIG. 1C illustrates a detailed cross-sectional view of a portion of the integrated device 100.

In the example illustrated in FIGS. 1A-1C, the integrated device 100 includes a die 102 having a plurality of contact pads (e.g., representative contact pad 106 illustrated in FIG. 1C). The integrated device 100 may correspond to or include an integrated circuit in which one or more circuit components 116 or structures are built within or on a surface of a substrate 104 and electrically connected to the contact pads. To illustrate, the circuit component(s) 116 can include transistors, conductive lines, passive electrical devices (e.g., inductors, capacitors, resistors, etc.), or other components arranged and interconnected to form one or more circuits. Additionally, or alternatively, the integrated device 100 can include an interposer device, in which case the circuit component(s) 116 can include conductive interconnect structures (e.g., conductive vias, conductive lines, etc.) coupled to the contact pads to facilitate electrical connections between two or more other integrated devices. The die 102 of the integrated device 100 can be packaged (i.e., at least partially encapsulated within a mold compound) or unpackaged. In an example in which the die 102 is unpackaged, the die 102 can include a chiplet that is configured to be electrically connected to one or more other chiplets or other dies.

In the detailed example illustrated in FIG. 1C, the contact pad 106 is integrated within or disposed on a surface of the substrate 104. To illustrate, the contact pad 106 can be deposited on the substrate 104. Additionally, in the detailed example of FIG. 1C, the die 102 includes one or more other layers disposed on the substrate 104. For example, the die 102 in FIG. 1C includes a passivation layer 110 and a polyimide layer 108, each of which covers at least a portion of a surface of the substrate 104 and/or the contact pad 106. Openings through the passivation layer 110 and the polyimide layer 108 enable access to the contact pads 106.

The integrated device 100 also includes a plurality of pillar bumps 132 that form a grid or array to enable electrical interconnection to another device (e.g., another die, a package substrate, or a printed circuit board). In a particular aspect, each of the pillar bumps 132 includes a multi-layer interconnect pillar 120 and a solder cap 130. Each of the solder caps 130 is electrically connected to a respective one of the contact pads 106 via a corresponding multi-layer interconnect pillar 120. As described in more detail below, the multi-layer interconnect pillars 120 are configured to enable electrical interconnection of the device 100 and another device, such as a printed circuit board, a package substrate, another die, etc. In particular, the multi-layer interconnect pillars 120 are configured to be pliable while also allowing close spacing of the pillar bumps 132. For example, a pitch 114 of the pillar bumps 132 can be less than or equal to 150 micrometers (such as less than or equal to 130 micrometers) enabling dense packing of electrical connections between the device 100 and a packaging substrate.

Using conventional solder bumps (i.e., without interconnect pillars) at such a fine pitch 114 is not feasible because when such solder bumps are heated sufficiently to reflow (e.g., to form bonds to another device), the solder bumps tend to merge, causing short circuits. An additional, and distinct, problem with using conventional solder bumps at such a fine pitch 114 is that the size of the solder bumps is so small that a stand-off distance between the die 102 and the device it is coupled to may not allow an underfill material to be adequately spread, leading to uneven stresses and insufficient support. Copper posts are sometimes used with solder bumps to mitigate some of these concerns. For example, copper posts can provide additional stand-off distance between the die 102 and a packaging substrate so that underfill material can be properly distributed. However, copper posts are much less pliable than solder bumps. As a result, when copper posts are used, various layers of the die 102 and/or a device to which the die 102 is coupled via the copper post can be damaged by stresses (e.g., thermally induced stresses due to differences in coefficients of thermal expansion) due, in part, to the rigidity of the copper post. One example of damage that can occur when copper posts are used is due to so called “extremely low k (ELK)” stress, which can cause cracking in brittle dielectric layers (e.g., layers with low dielectric constant (k) values) of the die 102. In contrast to conventional solder bumps and conventional copper posts, the multi-layer interconnect pillars 120 of the pillar bumps 132 include one or more solder layers disposed between reinforcement layers. In this stacking arrangement, the solder layers make the multi-layer interconnect pillars 120 less rigid (e.g., more compliant) than conventional copper pillars, which reduces damage such as cracking of ELK layer(s), while the reinforcement layers make the multi-layer interconnect pillars 120 more dimensionally stable than conventional solder bumps, thus enabling a fine pitch 114 between the pillar bumps 132.

As illustrated in FIG. 1C, the multi-layer interconnect pillar 120 includes a base reinforcement layer 122, a cap reinforcement layer 126, and a solder layer 124 disposed between the base reinforcement layer 122 and the cap reinforcement layer 126. The solder cap 130 is electrically connected to the multi-layer interconnect pillar 120, and via the multi-layer interconnect pillar 120, to the contact pad 106. Although two reinforcement layers (e.g., the base reinforcement layer 122 and the cap reinforcement layer 126) are illustrated in FIG. 1C, in other implementations, the multi-layer interconnect pillar 120 includes more than two reinforcement layers. Furthermore, although one solder layer (e.g., the solder layer 124) is illustrated in FIG. 1C, in other implementations, the multi-layer interconnect pillar 120 includes more than one solder layer. Optionally, the multi-layer interconnect pillar 120 can include other layers, such as a barrier layer between the cap reinforcement layer 126 and the solder cap 130, a copper layer (e.g., a copper pillar) between the contact pad 106 and the solder cap 130, or both.

In some implementations, one or more under bump metallization (UBM) layers 112 are coupled to and disposed between the contact pad 106 and the base reinforcement layer 122. For example, the UBM layer(s) 112 can include seed layers and/or adhesion layers that facilitate plating of the base reinforcement layer 122.

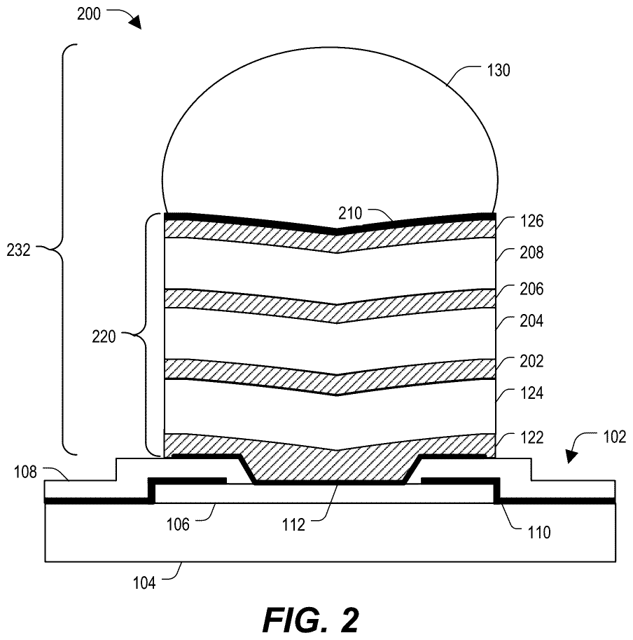

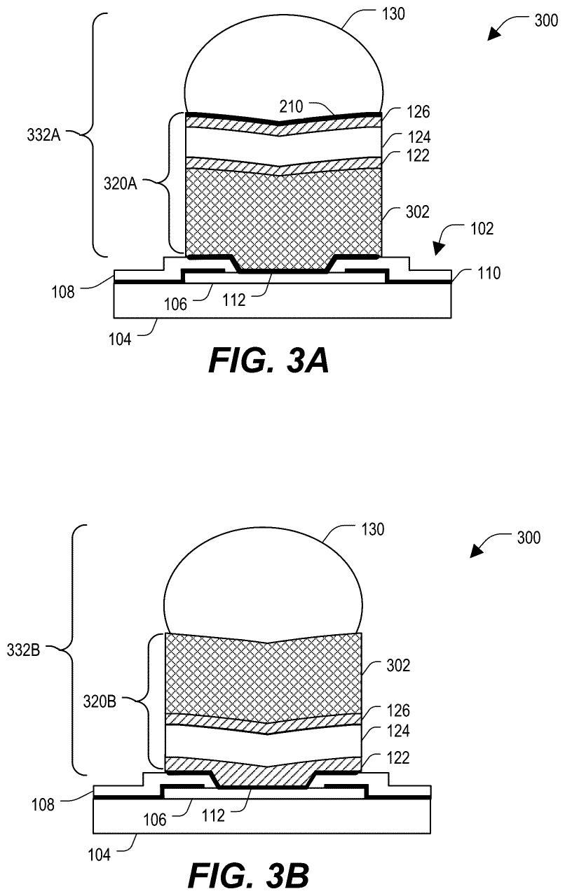

The material used to form the reinforcement layers is selected to have a higher melting point than a solder used to form the solder layer 124 and the solder cap 130. As an example, the solder can include a lead-free solder, such as a tin/silver solder, and the reinforcement layers can include nickel, cobalt, or alloys that include either. An additional consideration in selecting the material used to form the reinforcement layers is formation of intermetallic compounds (IMCs) by diffusion of the material of a reinforcement layer into the solder. Such IMCs are generally more brittle than the solder alone and may also have other undesirable mechanical and/or electrical properties. As one example, nickel in contact with the solder cap 130 can form IMCs within the solder cap 130, and such IMCs can lead to failure of a joint between the solder cap 130 and another device and/or can make wafer-level probe testing more difficult (leading to increased manufacturing costs). To reduce the formation of IMCs between the cap reinforcement layer 126 and the solder cap 130, a barrier layer (e.g., a barrier layer 210 of FIG. 2 or 3) can be formed between the solder cap 130 and the cap reinforcement layer 126. For example, when the cap reinforcement layer 126 includes nickel, the barrier layer can include copper. In implementations that include a barrier layer, the barrier layer is much thinner than other layers of the multi-layer interconnect pillar 120. For example, the barrier layer can be a few micrometers (e.g., 1 or 2 micrometers, or less), and the reinforcement layers 122, 126, the solder layer 124, or both, can be on the order of 5 to 20 micrometers each. It is noted that copper also forms IMCs with tin/silver solder, and at a rate that is greater than a rate of formation of IMCs between nickel or cobalt and the solder; however, testing has shown that solder/nickel IMCs can cause wafer-level probe and inspection errors, which are not caused by solder/copper IMCs. Thus, there are benefits to using a barrier layer that forms IMCs with the solder cap 130 at a rate that is greater than the rate at which the cap reinforcement layer 126 forms IMCs with the solder cap 130.

The thicknesses of the layers of the multi-layer interconnect pillar 120 are selected to provide a target stand-off distance between the die 102 and the device or substrate to which the die 102 is coupled via the solder cap 130 while retaining structural stability of the multi-layer interconnect pillar 120 and providing desired pliability characteristics of the multi-layer interconnect pillar 120. For example, a maximum thickness of the solder layer 124 (or solder layers, if more than one is used) may be limited by structural stability concerns since reflowing the solder cap 130 can also cause softening of the solder layer 124. Tests have demonstrated that a solder layer 124 with a thickness between 5 micrometers to 20 micrometers can be used without losing structural stability of the multi-layer interconnect pillar 120 during typical manufacturing and test conditions, such as heating during wafer-level probe testing or reflowing of the solder caps 130 to attach the die 102 to another device. Further, reinforcement layers can have thicknesses in the range of 1 micrometer to 5 micrometers, as one example. If the desired stand-off height is too large for use of a three-layer stack, as illustrated in FIG. 1C, other layers can be added between the base reinforcement layer 122 and the cap reinforcement layer 126 (as described with reference to FIG. 2), between the base reinforcement layer 122 and the contact pad 106 (as described with reference to FIG. 3A), between the cap reinforcement layer 126 and the solder cap 130 (as described with reference to FIG. 3B).

FIG. 2 illustrates a detailed cross-sectional view of a portion of an integrated device 200. The device 200 corresponds to one particular example of the device 100 of FIGS. 1A-1C. For example, the device 200 includes the die 102, which includes a plurality of contact pads 106 (a representative one of which is shown in FIG. 2). The contact pads 106 are electrically connected to pillar bumps 232, each of which includes a solder cap 130 and a multi-layer interconnect pillar 220. In the example illustrated in FIG. 2, the die 102 also includes the substrate 104, the passivation layer 110, the polyimide layer 108, and the UBM layer(s) 112, each of which is described with reference to FIGS. 1A-1C above.

In FIG. 2, the multi-layer interconnect pillar 220 includes the base reinforcement layer 122, the cap reinforcement layer 126, and the solder layer 124 disposed between the base reinforcement layer 122 and the cap reinforcement layer 126. The multi-layer interconnect pillar 220 of FIG. 2 also includes one or more additional solder layers, and one or more intermediate reinforcement layers between the solder layer 124 and the cap reinforcement layer 126 or between the solder layer 124 and the base reinforcement layer 122. For example, in FIG. 2, the multi-layer interconnect pillar 220 includes the base reinforcement layer 122 in contact with the UBM layer(s) 112, the solder layer 124 in contact with the base reinforcement layer 122, an intermediate reinforcement layer 202 in contact with the solder layer 124, a solder layer 204 in contact with the intermediate reinforcement layer 202, an intermediate reinforcement layer 206 in contact with the solder layer 204, and a solder layer 208 in contact with the intermediate reinforcement layer 206 and in contact with the cap reinforcement layer 126.

Although the example illustrated in FIG. 2 includes three solder layers arranged in an alternating stack with four reinforcement layers, the specific number of solder layers and reinforcement layers can be different in different implementations. For example, as explained above, the number of layers can be selected based on the height of the multi-layer interconnect pillar 220 desired to provide a target stand-off distance and the structural stability and compliance of the multi-layer interconnect pillar 220.

Although the example illustrated in FIG. 2 includes solder layers that have a greater height than reinforcement layers, the specific height of solder layers and reinforcement layers can be different in different implementations. For example, as explained above, the height of layers can be selected based on the height of the multi-layer interconnect pillar 220 desired to provide a target stand-off distance and the structural stability and compliance of the multi-layer interconnect pillar 220.

FIG. 2 also illustrates an optional barrier layer 210 between the cap reinforcement layer 126 and the solder cap 130. The barrier layer 210 reduces formation of IMCs due to diffusion of material of the cap reinforcement layer 126 into the solder cap 130. It is noted that the barrier layer 210 can be formed of a material that forms IMCs with the solder of the solder cap 130 (even at a rate that is greater than the rate at which the material of the cap reinforcement layer 126 does) because the IMCs formed by the material of the cap reinforcement layer 126 and solder cap 130 interface can cause probe and inspection errors. In contrast, IMCs formed by the material of the barrier layer 210 and the solder cap 130 do not interfere with probe and inspection (or cause less interference).

FIGS. 3A and 3B illustrate additional detailed cross-sectional views of a portion of an integrated device 300. The devices 300 of FIGS. 3A and 3B correspond to particular examples of the device 100 of FIGS. 1A-1C. For example, each of the devices 300 includes the die 102, which includes a plurality of contact pads 106 (a representative one of which is shown in each of FIGS. 3A and 3B). The contact pads 106 are electrically connected to respective pillar bumps 332 (e.g., a pillar bump 332A in FIG. 3A and a pillar bump 332B in FIG. 3B). Each pillar bump 332 includes a solder cap 130 and a multi-layer interconnect pillar 320 (e.g., a multi-layer interconnect pillar 320A in FIG. 3A and a multi-layer interconnect pillar 320B in FIG. 3B). In the example illustrated in FIGS. 3A and 3B, the die 102 also includes the substrate 104, the passivation layer 110, the polyimide layer 108, and the UBM layer(s) 112, each of which is described with reference to FIGS. 1A-1C above.

In FIG. 3A, the multi-layer interconnect pillar 320A includes the base reinforcement layer 122, the cap reinforcement layer 126, and the solder layer 124 disposed between the base reinforcement layer 122 and the cap reinforcement layer 126. The multi-layer interconnect pillar 320A of FIG. 3A also includes a copper pillar 302 between the base reinforcement layer 122 and the contact pad 106.

In FIG. 3B, the multi-layer interconnect pillar 320B includes the base reinforcement layer 122, the cap reinforcement layer 126, and the solder layer 124 disposed between the base reinforcement layer 122 and the cap reinforcement layer 126. The multi-layer interconnect pillar 320B of FIG. 3B also includes a copper pillar 302 between the cap reinforcement layer 126 and the solder cap 130.

The copper pillar 302 of either of FIGS. 3A or 3B is less than the full height of the multi-layer interconnect pillar 320. For example, the copper pillar 302 may have a height in a range of 20% to 50% of the total height of the pillar bump 322. To illustrate, if the pillar bump 322 has a total height of about 60 micrometers, the copper pillar 302 may have a height in the range of 10 micrometers to 30 micrometers.

As explained above, copper pillars are more rigid than a stacked arrangement of reinforcement layers and solder layers, such as described with reference to FIG. 2; however, forming the multiple layers shown in FIG. 2 can be time consuming since different processes and equipment are typically used to apply solder layers than are used to apply the reinforcement layers. As a result, forming a stack of alternating solder and reinforcement layers can involve moving wafers or dies between different tools, which is time consuming and introduces the possibility of damaging the wafers or dies. The copper pillar 302 can be used to reduce the number of layers of the multi-layer interconnect pillar 320, while retaining compliance associated with the layered arrangement of solder layers and reinforcement layers.

Although the examples illustrated in FIGS. 3A and 3B include one solder layer 124 arranged between the cap reinforcement layer 126 and the base reinforcement layer 122, in other implementations, one or more additional solder layers and reinforcement layers can be used with the copper pillar 302. To illustrate, the multi-layer interconnect pillar 320 can include the copper pillar 302, the base reinforcement layer 122, the solder layer 124, the cap reinforcement layer 126, one or more additional intermediate reinforcement layers between the base reinforcement layer 122 and the cap reinforcement layer 126, and one or more additional solder layers between the reinforcement layers. The specific number and thickness of the layers can be selected based on the height of the multi-layer interconnect pillar 320 desired to provide a target stand-off distance and the structural stability and compliance of the multi-layer interconnect pillar 320.

A technical benefit of the multi-layer interconnect pillars 120, 220, or 320 is that the multi-layer interconnect pillars 120, 220, or 320 provide electrical interconnections between the die and another device (e.g., in a flip chip arrangement), where the electrical interconnections are compliant so as to reduce (relative to copper pillars) interconnection stresses, such as ELK stresses. An additional technical benefit is that the multi-layer interconnect pillars 120, 220, or 320 provide enough stand-off distance between the die 102 and the other device such that underfill material or mold compound can be properly distributed. A further technical benefit is that the multi-layer interconnect pillars 120, 220, or 320 can be positioned much closer together than traditional solder bumps. In some implementations, each of the above-described technical benefits are provided. In other implementations, fewer than all of the above-described technical benefits are provided.

### Exemplary Sequences for Fabricating a Device Including Multi-layer Interconnect Pillar(s)

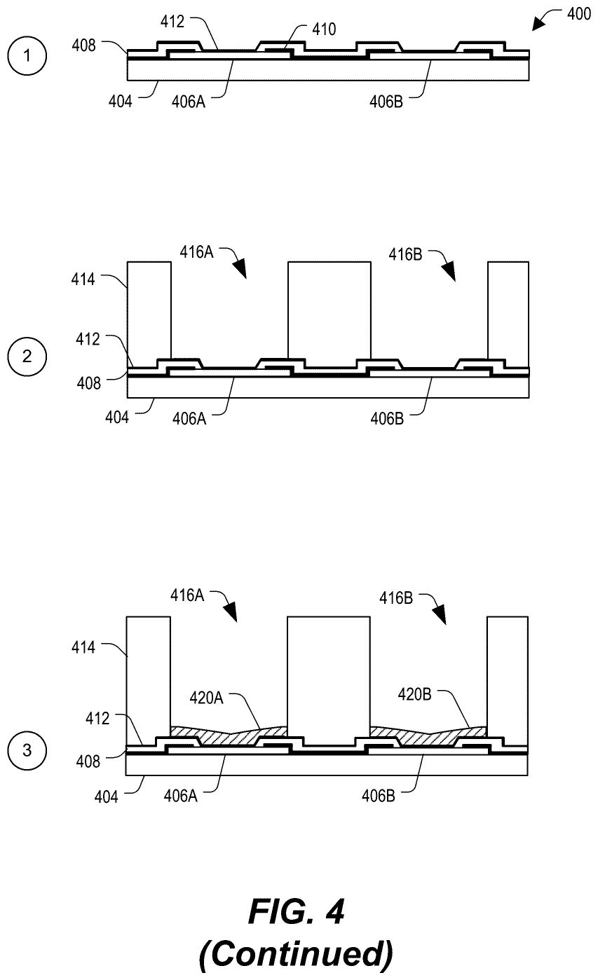

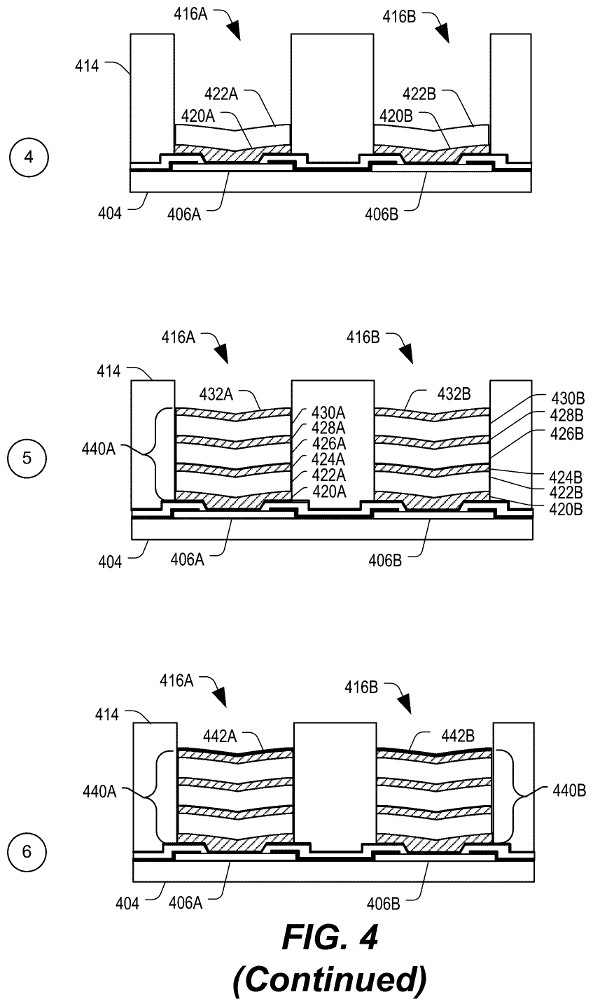

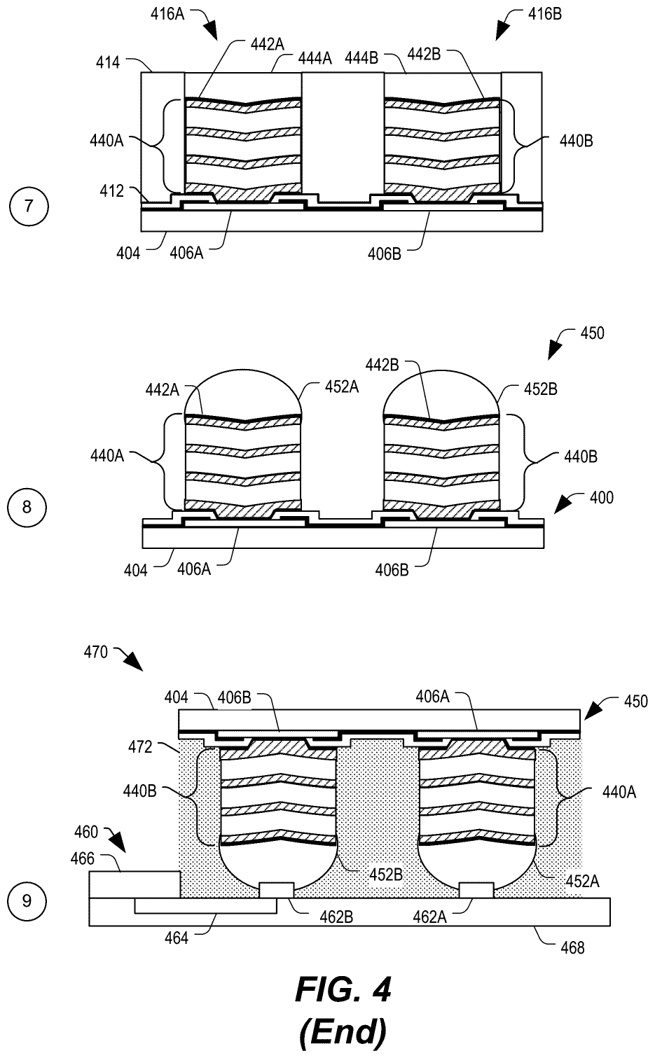

In some implementations, fabricating a device (e.g., any of the devices 100. 200, or 300) includes several processes. FIG. 4 (which is continued across several pages) illustrates a first exemplary sequence for providing or fabricating a device including pillar bumps, as described with reference to any of FIGS. 1A-3B. In some implementations, the sequence of FIG. 4 may be used to provide (e.g., during fabrication of) one or more of the devices 100, 200, or 300 of FIGS. 1A-3B.

It should be noted that the sequence of FIG. 4 may combine one or more stages in order to simplify and/or clarify the sequence for providing or fabricating an integrated device. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIG. 4. Each of the various stages of the sequence illustrated in FIG. 4 shows two pillar bumps being formed (e.g., concurrently in a die-level or wafer-level process) or used. In other implementations, more than two pillar bumps can be formed together concurrently and/or used together to attach a die to another device (e.g., another die, a package substrate, or a printed circuit board). Further, although each of the Stages in FIG. 4 illustrates operations associated with a single die, in some implementations, all of the operations described with reference to FIG. 4 except certain operations associated with the last Stage (i.e., Stage 9) can be performed at the wafer level or at the die level.

Stage 1 of FIG. 4 illustrates a state after a die 400 has been fabricated (e.g., using one or more FEOL processes, one or more MOL processes, one or more BEOL processes, or a combination thereof). As one example, the die 400 can be a portion of a wafer (e.g., a semiconductor wafer) that includes integrated circuitry formed in or on a substrate 404. The die 400 includes a plurality of contact pads 406 (including a contact pad 406A and a contact pad 406B). Optionally, the die 400 can include other structures, such as one or more passivation layers 410, one or more polyimide layers 408, one or more UBM layers 412, or a combination of thereof. As an example, the UBM layer(s) 412 can include or correspond to one or more adhesion layers, one or more barrier layers, one or more seed layers, or a combination thereof. To illustrate, in FIG. 4, the UBM layer(s) 412 can include a titanium layer or a titanium/tungsten layer as an adhesion/barrier layer. In a particular aspect, the die 400 corresponds to or includes the die 102 of any of FIGS. 1A-3B. For example, the contact pads 406 are electrically connected to circuit components within or on the substrate 404.

Stage 2 illustrates a state after a photoresist layer 414 has been applied to the die 400 (or a wafer including the die 400) and patterned to form openings 416 (including an opening 416A and an opening 416B) to enable access to the contact pads 406 and/or to the UBM layer 412. In a particular example, a deposition process, a spin-on process, or a similar process can be used to apply the photoresist layer 414, and the photoresist layer 414 can subsequently be selectively cured by exposing portions of the photoresist layer 414 to light (e.g., using a mask). Uncured portions of the photoresist layer 414 can be removed to form the openings 416. In some implementations, other patterned layers can be used in addition to or instead of the photoresist layer 414 to define the openings 416. For example, a heat curable polymer layer can be cured on the die 400 and subsequently patterned by laser ablation. As another example, a polymer layer can be applied and patterned at the same time, such as via an imprint lithography technique.

Stage 3 illustrates a state after a base reinforcement layer 420 has been formed. For example, forming the base reinforcement layer 420 can include electroplating the die 400 (or a wafer including the die 400) to deposit nickel, cobalt, or an alloy that includes either or both nickel and cobalt, on to a portion of the die 400 exposed via each opening 416. To illustrate, after Stage 2 of FIG. 4, a portion of the UBM layer 412 is exposed through the opening 416A, and the base reinforcement layer 420A can be formed on the exposed portion of the UBM layer 412 by depositing a metal using one or more electroplating operations to achieve the state illustrated at Stage 3. The base reinforcement layer 420B can be formed on another exposed portion of the UBM layer 412 in a similar manner (e.g., during the same electroplating operation(s) used to form the base reinforcement layer 420A). In other examples, other metal deposition techniques (such as sputtering or one or more evaporative techniques) can be used (alone or in combination with electroplating) to form the base reinforcement layers 420.

Stage 4 illustrates a state after a solder layer 422 has been formed on the base reinforcement layer 420. For example, forming the solder layer 422 can include electroplating the die 400 (or a wafer including the die 400) to deposit multiple metals of a lead-free solder alloy (e.g., a tin/silver alloy) on to the base reinforcement layer 420 exposed via each opening 416. To illustrate, in FIG. 4, after Stage 3 of FIG. 4, the base reinforcement layer 420A is exposed through the opening 416A, and the solder layer 422A can be formed on the base reinforcement layer 420A by depositing solder using one or more electroplating operations to achieve the state illustrated at Stage 4. The solder layer 422B can be formed on the base reinforcement layer 420B in a similar manner (e.g., during the same electroplating operation(s) used to form the solder layer 422A). In other examples, other metal deposition techniques (such as sputtering or one or more evaporative techniques) can be used (alone or in combination with electroplating) to form the solder layers 422.

Stage 5 illustrates a state after one or more intermediate reinforcement layers (e.g., intermediate reinforcement layers 424 and 428), one or more additional solder layers (e.g., additional solder layers 426 and 430), and a cap reinforcement layer 432 have been formed to define a multi-layer interconnect pillar 440. The intermediate reinforcement layer(s) 424, 428, and the cap reinforcement layer 432 can be formed using operations similar to those used to form the base reinforcement layer 420 (as described with reference to Stage 3 of FIG. 4). The additional solder layer(s) 426, 430 can be formed using operations similar to those used to form the solder layer 422 (as described with reference to Stage 4 of FIG. 4). For example, after Stage 4 of FIG. 4, the solder layer 422A is exposed through the opening 416A. In this example, the intermediate reinforcement layer 424A can be formed on the solder layer 422A by using one or more metal deposition operations, the additional solder layer 426A can be formed on the intermediate reinforcement layer 424A by using one or more metal deposition operations, and so forth, to achieve the state illustrated at Stage 5. The cap reinforcement layer 432 is formed as a final layer of the multi-layer interconnect pillar 440.

In the example illustrated at Stage 5 of FIG. 4, each multi-layer interconnect pillar 440 includes seven layers. For example, the multi-layer interconnect pillar 440A includes four reinforcement layers 420A, 424A, 428A, and 432A and three solder layers 422A, 426A, and 430A, and the multi-layer interconnect pillar 440B (labeled at Stage 6) includes four reinforcement layers 420B, 424B, 428B, and 432B and three solder layers 422B, 426B, and 430B. In other examples the operations described above can be used to form a multi-layer interconnect pillar 440 having more than seven layers or fewer than seven layers. To illustrate, the multi-layer interconnect pillar 120 of FIGS. 1A-1C can be formed using the operations described with reference to Stages 1-5 of FIG. 4 by depositing the cap reinforcement layer 432 on the solder layer 422 (i.e., omitting the intermediate reinforcement layers 424, 428 and the additional solder layers 426, 430).

Stage 6 illustrates a state after a barrier layer 442 has been formed on the cap reinforcement layer 432 of the multi-layer interconnect pillar 440. For example, forming the barrier layer 442 can include electroplating the die 400 (or a wafer including the die 400) to deposit a material to reduce formation of IMCs between the cap reinforcement layer 432 and a solder cap formed on the multi-layer interconnect pillar 440. The barrier layer 442 can include copper. As one example, after Stage 5 of FIG. 4, the cap reinforcement layer 432A is exposed through the opening 416A, and a barrier layer 442A can be formed on the cap reinforcement layer 432A by depositing a barrier metal using one or more electroplating operations to achieve the state illustrated at Stage 6. A barrier layer 442B can be formed on the cap reinforcement layer 432B in a similar manner (e.g., during the same electroplating operation(s) used to form the barrier layer 442A). In other examples, other metal deposition techniques (such as sputtering or one or more evaporative techniques) can be used (alone or in combination with electroplating) to form the barrier layers 442.

The barrier layers 442 are optional and are omitted in some implementations. For example, if IMCs formed by the solder and the cap reinforcement layer 432 do not interfere with other process operations, such as wafer-level probe and inspection, then the barrier layer 442 can be omitted.

Stage 7 illustrates a state after a solder layer 444 has been formed on the barrier layer 442 and/or on the multi-layer interconnect pillar 440. The solder layer 444 can be formed using one or more metal deposition operations, as described above with reference to formation of the solder layer 422 in Stage 4 of FIG. 4. For example, after Stage 6 of FIG. 4, the barrier layer 442A is exposed through the opening 416A, and a solder layer 444A can be formed on the barrier layer 442A by depositing solder using one or more electroplating operations to achieve the state illustrated at Stage 7. A solder layer 444B can be formed on the barrier layer 442B in a similar manner (e.g., during the same electroplating operation(s) used to form the solder layer 444A). In other examples, other metal deposition techniques (such as sputtering or one or more evaporative techniques) can be used (alone or in combination with electroplating) to form the solder layers 444.

Stage 8 illustrates a state after completion of formation of a device 450 that includes solder caps 452 electrically connected to contact pads 406 of a die 400 via respective multi-layer interconnect pillars 440 (and optional barrier layers 442). For example, after Stage 7 of FIG. 4, the photoresist layer 414 can be removed (e.g., using one or more thermal and/or chemical processes, such as ashing or stripping operations). Additionally, after Stage 7, one or more etching operations may be performed to remove portions of the UBM layer 412 that are not covered by the multi-layer interconnect pillars 440. Further, the solder layer 444 can be heated to reflow and form the solder caps 452 (including a solder cap 452A and a solder cap 452B). Additionally, in implementations in which the multi-layer interconnect pillars 440 and solder caps 452 are formed at a wafer level, a dicing operation can be performed to separate the device 450 from other portions of the wafer. In some such implementations, additional wafer-level processes can be performed before the dicing operations. To illustrate, wafer-level testing and/or inspection operations (e.g., wafer-level probe operations) can be performed to identify potential defects, which can be reworked or marked for later disposal or rework.

Formation of the device 450 is complete at Stage 8. For example, the device 450 can include or correspond to the device 100 of FIGS. 1A and 1B. The device 450 can be packaged (e.g., at least partially encapsulated in a mold compound) or unpackaged. The solder caps 452 can be used to electrically connect the device 450 to another device or to a package substrate. For example, the solder caps 452 can correspond to a grid or array of solder caps with a pitch 114, as illustrated in FIGS. 1A and 1B.

Stage 9 illustrates a state after formation of a device 470 that includes the device 450 coupled to another device 460 using the solder caps 452. For example, the device 450 can be flipped (relative to the orientation illustrated in Stage 8) and positioned such that each of the solder caps 452 is in contact with a respective electrical interface 462 (including an electrical interface 462A and an electrical interface 462B) of the device 460. In this example, the solder caps 452 can be heated to reflow and subsequently cooled to form a physical and electrical connection to the electrical interfaces 462. The electrical interfaces 462 can include, for example, contact pads, conductive lines, or other electrical interconnection interfaces.

The device 460 can include or correspond to a package substrate, a printed circuit board, or another packaged or unpackaged die. As one example, the device 450 and the device 460 are chiplets, which in Stage 9, are arranged and interconnected as a 3D stacked integrated circuit (IC). Arranging chiplets in this manner can provide various benefits as compared to providing the same functional circuitry in one monolithic chip. For example, each chiplet is smaller than a monolithic die including all of the same functional circuit blocks would be. Since yield loss in IC manufacturing tends to increase as the die size increases, using smaller dies can reduce yield loss (i.e., increase yield) of the IC manufacturing process. Another benefit is that the chiplets can be fabricated in different locations and/or by different manufacturers, and in some cases, using different fabrication technologies (e.g., different fabrication technology nodes). As an example, one die of a chiplet-based integrated device (e.g., the device 470) can include components (e.g., interconnects, transistors, etc.) that have a first minimum size, and another die of the chiplet-based integrated device (e.g., the device 470) can include components (e.g., interconnects, transistors, etc.) that have a second minimum size, where the second minimum size is greater than the first minimum size. In contrast, all of the circuitry of a monolithic die is fabricated using the same fabrication technologies and equipment. As a result, when manufacturing a monolithic die, the entire die may be subject to the tightest manufacturing constraint of the most complex component of the monolithic die. However, when using chiplets, different chiplets can be manufactured using different fabrication technologies (e.g., different fabrication technology nodes), and only the chiplet or chiplets that include the most complex components are subjected to the tightest manufacturing constraints. In this arrangement, chiplets fabricated using less expensive and/or higher yield fabrication technologies can be integrated with chiplets fabricated using more expensive and/or lower yield fabrication technologies to form a stacked IC (e.g., the device 470), resulting in overall savings. Still further, in some cases, as technology improves, the design of a chiplet can be changed. Chiplet stacking allows such new chiplet designs to be integrated with older chiplet designs to form stacked IC devices, which improves manufacturing flexibility and reduces design costs.

In the example illustrated in Stage 9 of FIG. 4, the device 460 includes a substrate 468, and one or more circuit components 466 formed on, disposed within, or coupled to the substrate 468. At least some of the electrical interfaces 462 are electrically connected (e.g., via conductive lines 464) to the circuit component(s) 466. Thus, connecting the solder caps 452 to the electrical interfaces 462 provides electrical connection(s) between circuit components of the device 450 (e.g., the component 116) and the circuit components 466 of the device 460.

The example illustrated in Stage 9 also shows a material 472 (e.g., an underfill material or mold compound) disposed between the device 450 and the device 460. The material 472 supports structural integrity of the device 470. The additional stand-off height provided by the multi-layer interconnect pillars 440 (relative to using solder bumps alone) facilitates relatively even distribution of the material 472 between the device 450 and the device 460. For example, the material 472 can include an epoxy or another polymer that is applied (e.g., injected between the device 450 and the device 460) as a viscous fluid, and subsequently hardened. In this example, the stand-off height provided by the multi-layer interconnect pillars 440 allows the viscous fluid to flow evenly between and around the multi-layer interconnect pillars 440 to reduce gaps and/or bubbles in the material 472.

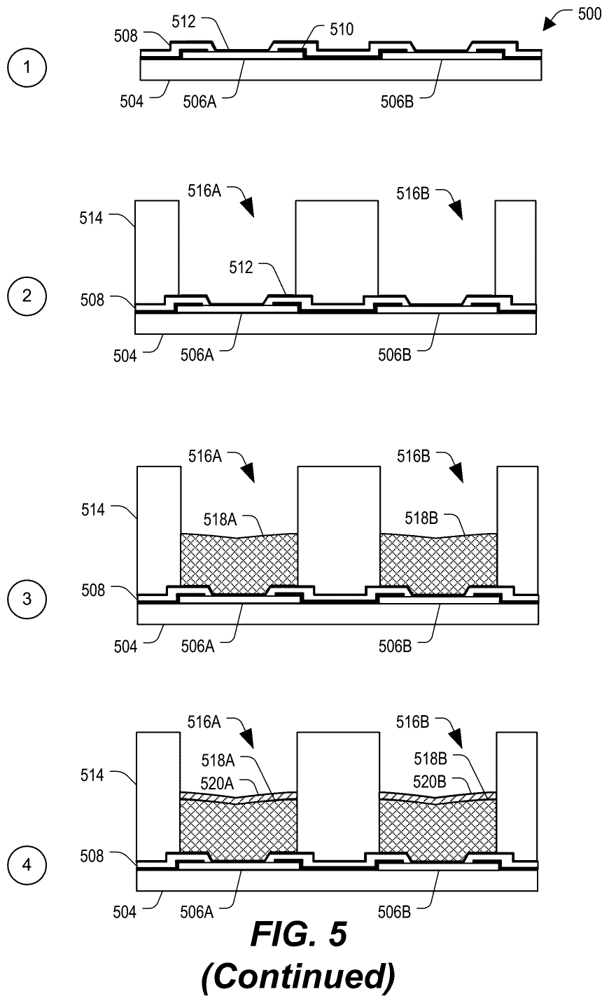

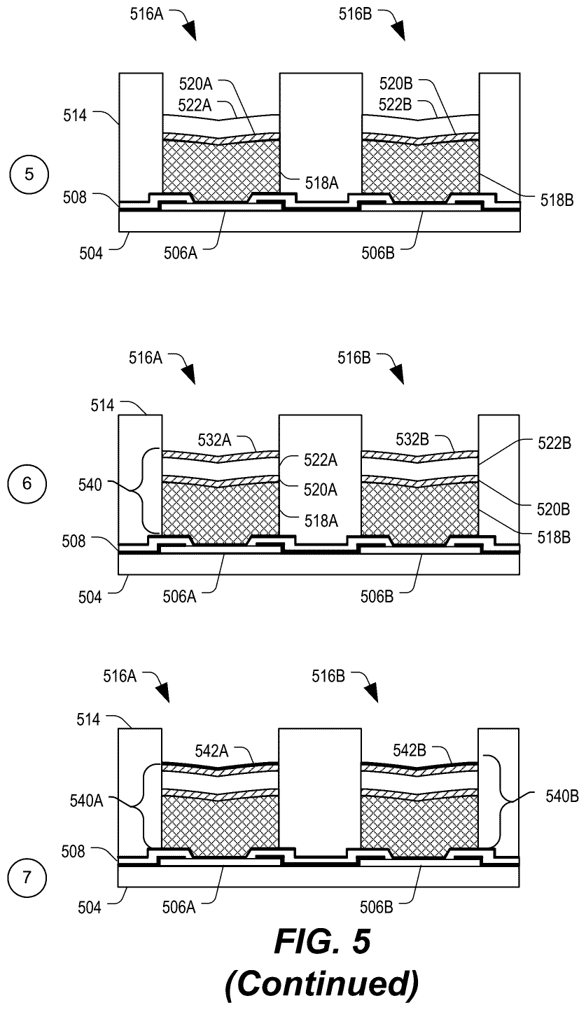

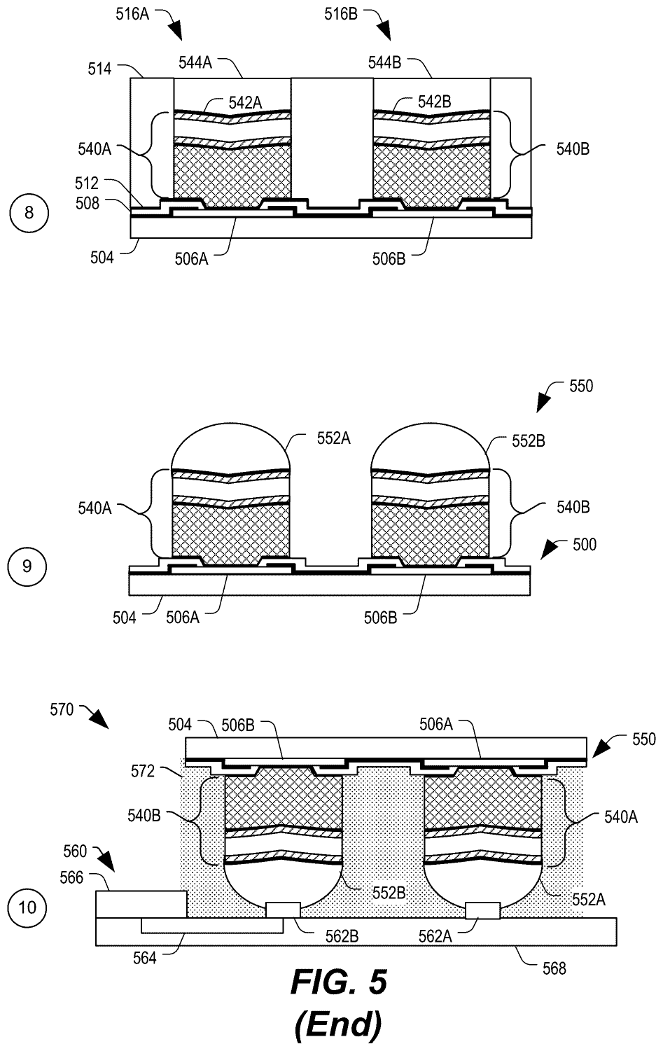

FIG. 5 (which is continued across several pages) illustrates a second exemplary sequence for providing or fabricating a device including one or more pillar bumps, as described with reference to any of FIGS. 1A-3B. In some implementations, the sequence of FIG. 5 may be used to provide (e.g., during fabrication of) one or more of the devices 100, 200, or 300 of FIGS. 1A-3B.

It should be noted that the sequence of FIG. 5 may combine one or more stages in order to simplify and/or clarify the sequence for providing or fabricating an integrated device. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIG. 5. Each of the various stages of the sequence illustrated in FIG. 5 shows two pillar bumps being formed (e.g., concurrently in a die level or wafer-level process) or used. In other implementations, more than two pillar bumps can be formed together concurrently and/or used together to attach a die to another device (e.g., another die, a package substrate, or a printed circuit board). Further, although each of the Stages in FIG. 5 illustrates operations associated with a single die, in some implementations, all of the operations described with reference to FIG. 5 except certain operations associated with the last Stage (i.e., Stage 10) can be performed at the wafer level or at the die level.

Stage 1 of FIG. 5 illustrates a state after a die 500 has been fabricated (e.g., using one or more FEOL processes, one or more MOL processes, one or more BEOL processes, or a combination thereof). As one example, the die 500 can be a portion of a wafer (e.g., a semiconductor wafer) that includes integrated circuitry formed in or on a substrate 504. The die 500 includes a plurality of contact pads 506 (including a contact pad 506A and a contact pad 506B). Optionally, the die 500 can include other structures, such as one or more passivation layers 510, one or more polyimide layers 508, one or more UBM layers 512, or a combination thereof. In a particular aspect, the die 500 corresponds to or includes the die 102 of any of FIGS. 1A-3B. For example, the contact pads 506 are electrically connected to circuit components within or on the substrate 504.

Stage 2 illustrates a state after a photoresist layer 514 has been applied to the die 500 (or a wafer including the die 500) and patterned to form openings 516 (including an opening 516A and an opening 516B) to enable access to the contact pads 506 and/or to the UBM layers 512. In a particular example, a deposition process, a spin-on process, or a similar process can be used to apply the photoresist layer 514, and the photoresist layer 514 can subsequently be selectively cured by exposing portions of the photoresist layer 514 to light (e.g., using a mask). Uncured portions of the photoresist layer 514 can be removed to form the openings 516. In some implementations, other patterned layers can be used in addition to or instead of the photoresist layer 514 to define the openings 516. For example, a heat curable polymer layer can be cured on the die 500 and subsequently patterned by laser ablation. As another example, a polymer layer can be applied and patterned at the same time, such as via an imprint lithography technique.

Stage 3 illustrates a state after copper pillars 518 have been formed. For example, forming a copper pillar 518 can include electroplating the die 500 (or a wafer including the die 500) to deposit copper on a portion of the die 500 exposed via each opening 516. To illustrate, after Stage 2 of FIG. 5, a portion of the UBM layer 512 is exposed through the opening 516A, and a copper pillar 518A can be formed on the exposed portion of the UBM layer 512 by depositing copper using one or more electroplating operations to achieve the state illustrated at Stage 3. A copper pillar 518B can be formed on another exposed portion of the UBM layer 512 in a similar manner (e.g., during the same electroplating operation(s) used to form the copper pillar 518A). In other examples, other metal deposition techniques (such as sputtering or one or more evaporative techniques) can be used (alone or in combination with electroplating) to form the copper pillars 518.

Stage 4 illustrates a state after base reinforcement layers 520 have been formed. For example, forming the base reinforcement layer 520 can include electroplating the die 500 (or a wafer including the die 500) to deposit nickel, cobalt, or an alloy that includes either or both nickel and cobalt, on the copper pillars 518. To illustrate, after Stage 3 of FIG. 5, the copper pillar 518A is exposed through the opening 516A, and a base reinforcement layer 520A can be formed on the copper pillar 518A by depositing a metal using one or more electroplating operations to achieve the state illustrated at Stage 4. A base reinforcement layer 520B can be formed on the copper pillar 518B in a similar manner (e.g., during the same electroplating operation(s) used to form the base reinforcement layer 520A). In other examples, other metal deposition techniques (such as sputtering or one or more evaporative techniques) can be used (alone or in combination with electroplating) to form the base reinforcement layers 520.

Stage 5 illustrates a state after solder layers 522 have been formed on the base reinforcement layers 520. For example, forming a solder layer 522 can include electroplating the die 500 (or a wafer including the die 500) to deposit multiple metals of a lead-free solder alloy (e.g., a tin/silver alloy) on to a base reinforcement layer 520 exposed via each opening 516. To illustrate, in FIG. 5, after Stage 4 of FIG. 5, the base reinforcement layer 520A is exposed through the opening 516A, and a solder layer 522A can be formed on the base reinforcement layer 520A by depositing solder using one or more electroplating operations to achieve the state illustrated at Stage 5. A solder layer 522B can be formed on the base reinforcement layer 520B in a similar manner (e.g., during the same electroplating operation(s) used to form the solder layer 522A). In other examples, other metal deposition techniques (such as sputtering or one or more evaporative techniques) can be used (alone or in combination with electroplating) to form the solder layers 522.

Stage 6 illustrates a state after cap reinforcement layers 532 have been formed to define multi-layer interconnect pillars 540. In some implementations, one or more intermediate reinforcement layers and one or more additional solder layers are formed before the cap reinforcement layers 532 are formed, as described with reference to Stage 5 of FIG. 4. In such implementations, a cap reinforcement layer 532 is formed as a final layer of a multi-layer interconnect pillar 540. Forming the cap reinforcement layer 532 can include electroplating the die 500 (or a wafer including the die 500) to deposit nickel, cobalt, or an alloy that includes either or both nickel and cobalt, on the solder layer 522. To illustrate, after Stage 5 of FIG. 5, the solder layer 522A exposed through the opening 516A, and a cap reinforcement layer 532A can be formed on the solder layer 522A by depositing a metal using one or more electroplating operations to achieve the state illustrated at Stage 6. A cap reinforcement layer 532B can be formed on the solder layer 522B in a similar manner (e.g., during the same electroplating operation(s) used to form the cap reinforcement layer 532A). In other examples, other metal deposition techniques (such as sputtering or one or more evaporative techniques) can be used (alone or in combination with electroplating) to form the cap reinforcement layers 532.

Stage 7 illustrates a state after barrier layers 542 have been formed on the cap reinforcement layers 532 of the multi-layer interconnect pillars 540. For example, forming a barrier layer 542 can include electroplating the die 500 (or a wafer including the die 500) to deposit a material to reduce formation of IMCs between a cap reinforcement layer 532 and a solder cap formed on a multi-layer interconnect pillar 540. The barrier layers 542 can include copper. As one example, after Stage 6 of FIG. 5, the cap reinforcement layer 532A is exposed through the opening 516A, and a barrier layer 542A can be formed on the cap reinforcement layer 532A by depositing a barrier metal using one or more electroplating operations to achieve the state illustrated at Stage 7. A barrier layer 542B can be formed on the cap reinforcement layer 532B in a similar manner (e.g., during the same electroplating operation(s) used to form the barrier layer 542A). In other examples, other metal deposition techniques (such as sputtering or one or more evaporative techniques) can be used (alone or in combination with electroplating) to form the barrier layers 542.

The barrier layers 542 are optional and are omitted in some implementations. For example, if the IMCs formed by the solder and the cap reinforcement layer 532 will not interfere with other process steps, such as wafer-level probe or inspection, then the barrier layer 542 can be omitted.

The operations associated with Stages 3-6 of FIG. 5 are illustrated and described in an order that would be used to form the pillar bump 332A of FIG. 3A. The same or similar operations can be performed in a different order to form the pillar bump 332B of FIG. 3B. For example, to form the multi-layer interconnect pillar 320B of FIG. 3B, operations to form the base reinforcement layers 520, the solder layers 520, and the cap reinforcement layers 532 (as described with reference to Stages 4-6) are performed before the copper pillars 518 are formed (as described with reference to Stage 3). When the copper pillars 518 are formed on a stack including the base reinforcement layers 520, the solder layers 520, and the cap reinforcement layers 532, the barrier layer 542 (as described with reference to Stage 7) can be omitted.

Stage 8 illustrates a state after solder layers 544 have been formed on the barrier layers 542 and/or on the multi-layer interconnect pillars 540. A solder layer 544 can be formed using one or more metal deposition operations, as described above with reference to Stage 5 of FIG. 5. For example, after Stage 7 of FIG. 5, the barrier layer 542A is exposed through the opening 516A, and a solder layer 544A can be formed on the barrier layer 542A by depositing solder using one or more electroplating operations to achieve the state illustrated at Stage 8. A solder layer 544B can be formed on the barrier layer 542B in a similar manner (e.g., during the same electroplating operation(s) used to form the solder layer 544A). In other examples, other metal deposition techniques (such as sputtering or one or more evaporative techniques) can be used (alone or in combination with electroplating) to form the solder layers 544. When forming the pillar bump 322B of FIG. 3B, the solder layers 544 are formed on the copper pillars 518 rather than on the barrier layers 542 or the cap reinforcement layers 532.

Stage 9 illustrates a state after completion of formation of a device 550 that includes solder caps 552 (including a solder cap 552A and a solder cap 552B) electrically connected to contact pads 506 of a die 500 via respective multi-layer interconnect pillars 540 (and optional barrier layers 542). For example, after Stage 8 of FIG. 5, the photoresist layer 514 can be removed (e.g., using one or more thermal and/or chemical processes, such as ashing or stripping operations). Additionally, after Stage 8, one or more etching operations may be performed to remove portions of the UBM layer 512 that are not covered by the multi-layer interconnect pillars 540. Further, the solder layer 544 can be heated to reflow and form the solder caps 552. Additionally, in implementations in which the multi-layer interconnect pillars 540 and the solder caps 552 are formed at a wafer level, a dicing operation can be performed to separate the device 550 from other portions of the wafer. In some such implementations, additional wafer-level processes can be performed before the dicing operations. To illustrate, wafer-level testing and/or inspection operations (e.g., wafer-level probe operations) can be performed to identify potential defects, which can be reworked or marked for later disposal or rework.

Formation of the device 550 is complete at Stage 9. For example, the device 550 can include or correspond to the device 100 of FIGS. 1A and 1B or to the device 300 of FIGS. 3A or 3B. The device 550 can be packaged (e.g., at least partially encapsulated in a mold compound) or unpackaged. The solder caps 552 can be used to electrically connect the device 550 to another device. For example, the solder caps 552 can correspond to a grid or array of solder caps with a pitch 114, as illustrated in FIGS. 1A and 1B.

Stage 10 illustrates a state after formation of a device 570 that includes the device 550 coupled to another device 560 using the solder caps 552. For example, the device 550 can be flipped (relative to the orientation illustrated in Stage 9) and positioned such that each of the solder caps 552 is in contact with a respective electrical interface 562 (including an electrical interface 562A and an electrical interface 562B) of the device 560. In this example, the solder caps 554 can be heated to reflow and subsequently cooled to form a physical and electrical connection to the electrical interfaces 562. The electrical interfaces 562 can include, for example, contact pads, conductive lines, or other electrical interconnection interfaces.

The device 560 can include or correspond to a package substrate, a printed circuit board, or another packaged or unpackaged die. As one example, the device 550 and the device 560 are chiplets, which in Stage 10, are arranged and interconnected as a 3D stacked IC. A material 572 (e.g., an underfill material or a mold compound) may be disposed between the device 550 and the device 560.

In the example illustrated in Stage 10 of FIG. 5, the device 560 includes a substrate 568, and one or more circuit components 566 formed on, disposed within, or coupled to the substrate 568. At least some of the electrical interfaces 562 are electrically connected (e.g., via conductive lines 564) to the circuit component(s) 566. Thus, connecting the solder caps 552 to the electrical interfaces 562 provides electrical connection(s) between circuit components of the device 550 (e.g., the component 116) and the circuit components 566 of the device 560.

### Exemplary Flow Diagram of a Method for Fabricating a Device Including Multi-Layer Interconnect Pillar(s)

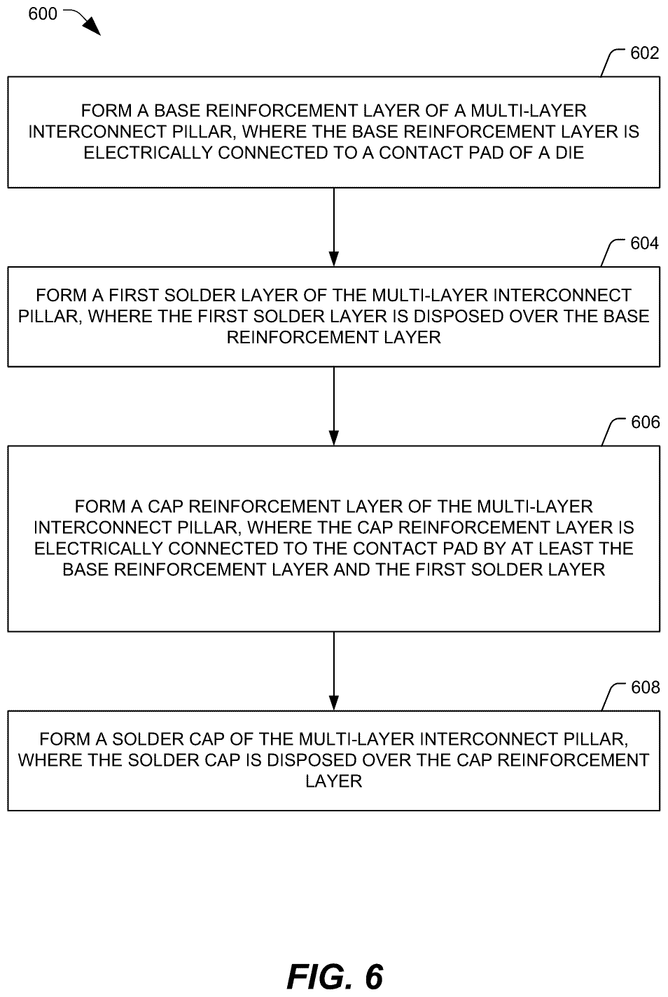

In some implementations, fabricating a device that includes a multi-layer interconnect pillar includes several processes. FIG. 6 illustrates an exemplary flow diagram of a method 600 for providing or fabricating a stacked IC device. In some implementations, the method 600 of FIG. 6 may be used to provide or fabricate any of the devices 100, 200, 300, 450, 470, 550, or 570 of FIGS. 1A-5.

It should be noted that the method 600 of FIG. 6 may combine one or more processes in order to simplify and/or clarify the method for providing or fabricating an integrated device. In some implementations, the order of the processes may be changed or modified.

The method 600 includes, at 602, forming a base reinforcement layer of a multi-layer interconnect pillar, where the base reinforcement layer is electrically connected to a contact pad of a die. For example, the base reinforcement layer can be deposited onto the contact pad of the die. In some implementations, before forming the base reinforcement layer, the method 600 includes forming one or more UBM layers, where at least one of the one or more UBM layers contacts the contact pad. In such implementations, the base reinforcement layer can be deposited onto the UBM layers. Stage 3 of FIG. 4 illustrates and describes an example of one such implementation. Additionally, or alternatively, in some implementations, before forming the base reinforcement layer, the method 600 includes forming a copper pillar of the multi-layer interconnect pillar, where the copper pillar is disposed over the contact pad. In such implementations, the base reinforcement layer can be deposited onto the copper pillar. Stage 4 of FIG. 5 illustrates and describes an example of one such implementation.

The method 600 includes, at 604, forming a first solder layer of the multi-layer interconnect pillar, where the first solder layer is disposed over the base reinforcement layer. For example, the first solder layer may include a lead-free solder, such as a tin/silver alloy, which can be deposited on the base reinforcement layer using one or more electroplating operations or other metallization operations. Stage 4 of FIG. 4 and Stage 5 of FIG. 5 illustrate and describe examples of operations to form the first solder layer.

The method 600 includes, at 606, forming a cap reinforcement layer of the multi-layer interconnect pillar, where the cap reinforcement layer is electrically connected to the contact pad by at least the base reinforcement layer and the first solder layer. For example, the cap reinforcement layer can be deposited onto the first solder layer. Stage 6 of FIG. 5 illustrates and describes one example of depositing the cap reinforcement layer 532 on the solder layer 522.

In other examples, one or more additional reinforcement layers between the base reinforcement layer and the cap reinforcement layer and one or more additional solder layers disposed between adjacent reinforcement layers are formed before the cap reinforcement layer is formed. Stage 5 of FIG. 4 illustrates and describes one example of forming one or more additional reinforcement layers (e.g., intermediate reinforcement layers 424, 428) and one or more additional solder layers (e.g., additional solder layers 426, 430) before the cap reinforcement layer 432 is formed.

In some implementations, the method 600 includes forming a copper pillar on a stack that includes at least the base reinforcement layer, the first solder layer, and the cap reinforcement layer (e.g., as illustrated for the multi-layer interconnect pillar 320B of FIG. 3B). In such implementations, operations described with reference to Stages 4-6 of FIG. 5 may be performed before operations associated with Stage 3 of FIG. 5.

The method 600 includes, at 608, forming a solder cap of the multi-layer interconnect pillar, where the solder cap is disposed over the cap reinforcement layer. For example, the solder cap can be formed by deposition of a solder layer over the cap reinforcement layer (or the copper pillar when the copper pillar is over the cap reinforcement layer). The solder layer can subsequently be heated to form the solder cap. Stage 8 of FIG. 4 and Stage 9 of FIG. 5 illustrate and describe examples of operations to form the solder cap.

In some implementations, before forming the solder cap, the method 600 includes forming one or more barrier layers, where at least one of the one or more barrier layers contacts the cap reinforcement layer. For example, a layer of a barrier metal (e.g., copper) can be deposited on the cap reinforcement layer to form the barrier layer. In this example, the solder cap is subsequently formed on the barrier layer. Stage 6 of FIG. 4 and Stage 7 of FIG. 5 illustrate and describe examples of operations to form the barrier layer.

In a particular example of the method 600, a photoresist layer is formed on the die (or a wafer that includes the die) and the photoresist layer is patterned to form opening(s) exposing the contact pad(s). In this example, the base reinforcement layer, the first solder layer, the cap reinforcement layer, and a solder layer of the solder cap are formed in the opening(s). In this example, after forming at least the base reinforcement layer, the first solder layer, the cap reinforcement layer, and the solder layer of the solder cap in the opening(s), the method 600 includes stripping the photoresist layer from the die (or the wafer) to expose the multi-layer interconnect pillar. Stage 2 of FIG. 4 and Stage 2 of FIG. 5 illustrate and describe examples of operations to apply and pattern the photoresist layer, and Stage 8 of FIG. 4 and Stage 9 of FIG. 5 illustrate and describe examples of operations to remove the photoresist layer.

In some implementations, after forming at least the base reinforcement layer, the first solder layer, the cap reinforcement layer, and the solder cap, the method 600 includes applying heat to the multi-layer interconnect pillar sufficient to soften the solder cap and one or more solder layers of the multi-layer interconnect pillar. In such implementations, the reinforcement layers limit deformation of the multi-layer interconnect pillar due to heating (e.g., due to softening of the solder).

In some implementations, the method 600 also includes, after forming at least the base reinforcement layer, the first solder layer, the cap reinforcement layer, and the solder cap, attaching the solder cap to another device to electrically connect the other device and the contact pad. For example, the solder cap and the multi-layer interconnect structure including at least the base reinforcement layer, the first solder layer, and the cap reinforcement layer can provide an electrical connection between the contact pad and an electrical interface of the other device. Stage 9 of FIG. 4 and Stage 10 of FIG. 5 illustrate and describe examples of operations to connect the solder cap to another device.

### Exemplary Electronic Devices

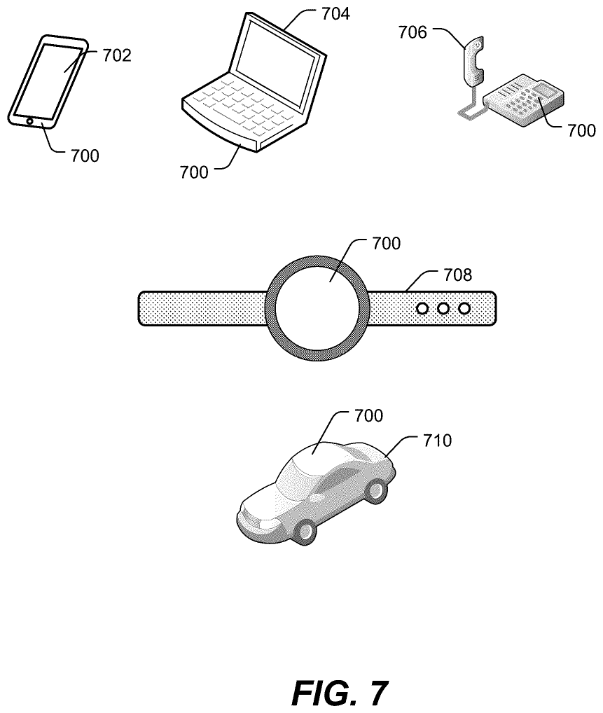

FIG. 7 illustrates various electronic devices that may include or be integrated with any of the devices 100, 200, 300, 450, 470, 550, or 570. For example, a mobile phone device 702, a laptop computer device 704, a fixed location terminal device 706, a wearable device 708, or a vehicle 710 (e.g., an automobile or an aerial device) may include a device 700. The device 700 can include, for example, any of the devices 100, 200, 300, 450, 470, 550, or 570 described herein. The devices 702, 704, 706 and 708 and the vehicle 710 illustrated in FIG. 7 are merely exemplary. Other electronic devices may also feature the device 700 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1A-7 may be rearranged and/or combined into a single component, process, feature or function or embodied in several components, processes, or functions. Additional elements, components, processes, and/or functions may also be added without departing from the disclosure. It should also be noted that FIGS. 1A-7 and their corresponding descriptions in the present disclosure are not limited to dies and/or ICs. In some implementations, FIGS. 1A-7 and their corresponding descriptions may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C. then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or a UBM layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, an integrated device includes a die having a contact pad; and a solder cap electrically connected to the contact pad by a multi-layer interconnect pillar, the multi-layer interconnect pillar includes a base reinforcement layer; a cap reinforcement layer; and a solder layer disposed between the base reinforcement layer and the cap reinforcement layer.

Example 2 includes the integrated device of Example 1 and further includes one or more UBM layers coupled to and disposed between the contact pad and the multi-layer interconnect pillar.

Example 3 includes the integrated device of Example 1 or Example 2 and further includes a barrier layer coupled to and disposed between the solder cap and the multi-layer interconnect pillar.

Example 4 includes the integrated device of Example 3, wherein a material of the solder cap forms IMCs with a material of the barrier layer at a first rate, wherein the material of the solder cap forms IMCs with a material of the cap reinforcement layer at a second rate, and wherein the first rate is greater than the second rate.

Example 5 includes the integrated device of Example 3 or Example 4, wherein the barrier layer comprises copper.

Example 6 includes the integrated device of any of Examples 1 to 5, wherein the multi-layer interconnect pillar further comprises an intermediate reinforcement layer disposed between the solder layer and the base reinforcement layer and a second solder layer disposed between the intermediate reinforcement layer and the cap reinforcement layer.

Example 7 includes the integrated device of any of Examples 1 to 6, wherein the multi-layer interconnect pillar further comprises one or more intermediate reinforcement layers disposed between the cap reinforcement layer and the base reinforcement layer and one or more additional solder layers, wherein solder layers and reinforcement layers alternate in the multi-layer interconnect pillar.

Example 8 includes the integrated device of Example 7, wherein each of the one or more additional solder layers has a thickness between 5 micrometers to 20 micrometers.

Example 9 includes the integrated device of any of Examples 1 to 8, wherein the multi-layer interconnect pillar further comprises a copper pillar between the base reinforcement layer and the contact pad.

Example 10 includes the integrated device of Example 9, wherein the copper pillar has a height of 10 micrometers to 40 micrometers.

Example 11 includes the integrated device of any of Examples 1 to 10, wherein the contact pad is one of a plurality of contact pads of the die, and the solder cap is one of a plurality of solder caps, wherein each of the plurality of solder caps is electrically connected to a respective one of the plurality of contact pads, and wherein a pitch of the plurality of solder caps is less than 150 micrometers.

Example 12 includes the integrated device of Example 11, wherein the pitch is less than 130 micrometers.

Example 13 includes the integrated device of any of Examples 1 to 12, wherein the cap reinforcement layer and the base reinforcement layer comprise nickel.

Example 14 includes the integrated device of any of Examples 1 to 13, wherein the cap reinforcement layer and the base reinforcement layer comprise cobalt.

According to Example 15, a method includes forming a base reinforcement layer of a multi-layer interconnect pillar, where the base reinforcement layer is electrically connected to a contact pad of a die; forming a first solder layer of the multi-layer interconnect pillar, wherein the first solder layer is disposed over the base reinforcement layer; forming a cap reinforcement layer of the multi-layer interconnect pillar, wherein the cap reinforcement layer is electrically connected to the contact pad by at least the base reinforcement layer and the first solder layer; and forming a solder cap of the multi-layer interconnect pillar, wherein the solder cap is disposed over the cap reinforcement layer.

Example 16 includes the method of Example 15 and further includes forming one or more additional reinforcement layers between the base reinforcement layer and the cap reinforcement layer; and forming one or more additional solder layers disposed between adjacent reinforcement layers.

Example 17 includes the method of Example 15 or Example 16 and further includes forming a copper pillar of the multi-layer interconnect pillar, wherein the copper pillar is disposed over the contact pad.

Example 18 includes the method of any of Examples 15 to 17 and further includes, before forming the base reinforcement layer, forming one or more UBM layers, wherein at least one of the one or more UBM layers contacts the contact pad.

Example 19 includes the method of any of Examples 15 to 18 and further includes, before forming the solder cap, forming one or more barrier layers, wherein at least one of the one or more barrier layers contacts the cap reinforcement layer.

Example 20 includes the method of any of Examples 15 to 19 and further includes forming a photoresist layer on the die; and patterning the photoresist layer to form an opening exposing the contact pad, wherein the base reinforcement layer, the first solder layer, the cap reinforcement layer, and a solder layer of the solder cap are formed in the opening.

Example 21 includes the method of Example 20 and further includes, after forming at least the base reinforcement layer, the first solder layer, the cap reinforcement layer, and the solder layer of the solder cap in the opening, stripping the photoresist layer from the die to expose the multi-layer interconnect pillar.

Example 22 includes the method of any of Examples 15 to 21 and further includes, after forming at least the base reinforcement layer, the first solder layer, the cap reinforcement layer, and the solder cap, applying heat to the multi-layer interconnect pillar sufficient to soften the solder cap and one or more solder layers of the multi-layer interconnect pillar, wherein reinforcement layers of the multi-layer interconnect pillar limit deformation of the multi-layer interconnect pillar due to heating.

Example 23 includes the method of any of Examples 15 to 22 and further includes, after forming at least the base reinforcement layer, the first solder layer, the cap reinforcement layer, and the solder cap, attaching the solder cap to another device to electrically connect the other device and the contact pad.

According to Example 24, a device includes a substrate including an interface; a die including a contact pad; a multi-layer interconnect pillar disposed between the substrate and the die and electrically connected to the contact pad, the multi-layer interconnect pillar includes a base reinforcement layer; a cap reinforcement layer; and a solder layer disposed between the base reinforcement layer and the cap reinforcement layer. The device also includes a solder cap electrically connected to the multi-layer interconnect pillar and to the interface.

Example 25 includes the device of Example 24 and further includes one or more UBM layers coupled to and disposed between the contact pad and to the multi-layer interconnect pillar.

Example 26 includes the device of Example 24 or Example 25 and further includes a barrier layer coupled to and disposed between the solder cap and the multi-layer interconnect pillar.

Example 27 includes the device of Example 26, wherein a material of the solder cap forms IMCs with a material of the barrier layer at a first rate, wherein the material of the solder cap forms IMCs with a material of the cap reinforcement layer at a second rate, and wherein the first rate is greater than the second rate.

Example 28 includes the device of Example 26 or Example 27, wherein the barrier layer comprises copper.

Example 29 includes the device of any of Examples 24 to 28, wherein the multi-layer interconnect pillar further comprises an intermediate reinforcement layer disposed between the solder layer and the base reinforcement layer; and a second solder layer disposed between the intermediate reinforcement layer and the cap reinforcement layer.

Example 30 includes the device of any of Examples 24 to 29, wherein the multi-layer interconnect pillar further comprises one or more intermediate reinforcement layers disposed between the cap reinforcement layer and the base reinforcement layer; and one or more additional solder layers, wherein solder layers and reinforcement layers alternate in the multi-layer interconnect pillar.

Example 31 includes the device of Example 30, wherein each of the one or more additional solder layers has a thickness between 5 micrometers to 20 micrometers.

Example 32 includes the device of any of Examples 24 to 31, wherein the multi-layer interconnect pillar further comprises a copper pillar between the base reinforcement layer and the contact pad.

Example 33 includes the device of Example 32, wherein the copper pillar has a height of 10 micrometers to 40 micrometers.

Example 34 includes the device of any of Examples 24 to 33, wherein the solder cap is one of a plurality of solder caps electrically connecting the die and the substrate, and wherein a pitch of the plurality of solder caps is less than 150 micrometers.

Example 35 includes the device of Example 34, wherein the pitch is less than 130 micrometers.

Example 36 includes the device of any of Examples 24 to 35, wherein the cap reinforcement layer and the base reinforcement layer comprise nickel.

Example 37 includes the device of any of Examples 24 to 36, wherein the cap reinforcement layer and the base reinforcement layer comprise cobalt.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. An integrated device comprising:
a die having a contact pad; and
a solder cap electrically connected to the contact pad by a multi-layer interconnect pillar, the multi-layer interconnect pillar comprising:
a base reinforcement layer;
a cap reinforcement layer; and
a solder layer disposed between the base reinforcement layer and the cap reinforcement layer.

2. The integrated device of 1, further comprising one or more under bump metallization (UBM) layers coupled to and disposed between the contact pad and the multi-layer interconnect pillar.

3. The integrated device of claim 1, further comprising a barrier layer coupled to and disposed between the solder cap and the multi-layer interconnect pillar.

4. The integrated device of claim 3, wherein a material of the solder cap forms Intermetallic compounds (IMCs) with a material of the barrier layer at a first rate, wherein the material of the solder cap forms IMCs with a material of the cap reinforcement layer at a second rate, and wherein the first rate is greater than the second rate.

5. The integrated device of claim 3, wherein the barrier layer comprises copper.

6. The integrated device of claim 1, wherein the multi-layer interconnect pillar further comprises:
one or more intermediate reinforcement layers disposed between the cap reinforcement layer and the base reinforcement layer; and
one or more additional solder layers, wherein solder layers and reinforcement layers alternate in the multi-layer interconnect pillar.

7. The integrated device of claim 6, wherein each of the one or more additional solder layers has a thickness between 5 micrometers to 20 micrometers.

8. The integrated device of claim 1, wherein the multi-layer interconnect pillar further comprises a copper pillar between the base reinforcement layer and the contact pad.

9. The integrated device of claim 8, wherein the copper pillar has a height between 10 micrometers to 40 micrometers.

10. The integrated device of claim 1, wherein the contact pad is one of a plurality of contact pads of the die, and the solder cap is one of a plurality of solder caps, wherein each of the plurality of solder caps is electrically connected to a respective one of the plurality of contact pads, and wherein a pitch of the plurality of solder caps is less than 150 micrometers.

11. The integrated device of claim 10, wherein the pitch is less than 130 micrometers.

12. The integrated device of claim 1, wherein the cap reinforcement layer and the base reinforcement layer comprise nickel.

13. The integrated device of claim 1, wherein the cap reinforcement layer and the base reinforcement layer comprise cobalt.

14. A method comprising:
forming a base reinforcement layer of a multi-layer interconnect pillar, the base reinforcement layer electrically connected to a contact pad of a die;
forming a first solder layer of the multi-layer interconnect pillar, wherein the first solder layer is disposed over the base reinforcement layer;
forming a cap reinforcement layer of the multi-layer interconnect pillar, wherein the cap reinforcement layer is electrically connected to the contact pad by at least the base reinforcement layer and the first solder layer; and
forming a solder cap of the multi-layer interconnect pillar, wherein the solder cap is disposed over the cap reinforcement layer.

15. The method of claim 14, further comprising:
forming one or more additional reinforcement layers between the base reinforcement layer and the cap reinforcement layer; and
forming one or more additional solder layers disposed between adjacent reinforcement layers.

16. The method of claim 14, further comprising forming a copper pillar of the multi-layer interconnect pillar, wherein the copper pillar is disposed over the contact pad.

17. The method of claim 14, further comprising, before forming the base reinforcement layer, forming one or more under bump metallization (UBM) layers, wherein at least one of the one or more UBM layers contacts the contact pad.

18. The method of claim 14, further comprising, before forming the solder cap, forming one or more barrier layers, wherein at least one of the one or more barrier layers contacts the cap reinforcement layer.

19. The method of claim 14, further comprising:
forming a photoresist layer on the die; and
patterning the photoresist layer to form an opening exposing the contact pad, wherein the base reinforcement layer, the first solder layer, the cap reinforcement layer, and a solder layer of the solder cap are formed in the opening.

20. The method of claim 19, further comprising, after forming at least the base reinforcement layer, the first solder layer, the cap reinforcement layer, and the solder layer of the solder cap in the opening, stripping the photoresist layer from the die to expose the multi-layer interconnect pillar.

21. The method of claim 14, further comprising, after forming at least the base reinforcement layer, the first solder layer, the cap reinforcement layer, and the solder cap, applying heat to the multi-layer interconnect pillar sufficient to soften the solder cap and one or more solder layers of the multi-layer interconnect pillar, wherein reinforcement layers of the multi-layer interconnect pillar limit deformation of the multi-layer interconnect pillar due to heating.

22. The method of claim 14, further comprising, after forming at least the base reinforcement layer, the first solder layer, the cap reinforcement layer, and the solder cap, attaching the solder cap to another device to electrically connect the other device and the contact pad.

23. A device comprising:
a substrate including an interface;
a die including a contact pad;
a multi-layer interconnect pillar disposed between the substrate and the die and electrically connected to the contact pad, the multi-layer interconnect pillar comprising:
a base reinforcement layer;
a cap reinforcement layer; and
a solder layer disposed between the base reinforcement layer and the cap reinforcement layer; and
a solder cap electrically connected to the multi-layer interconnect pillar and to the interface.

24. The device of 23, further comprising one or more under bump metallization (UBM) layers coupled to and disposed between the contact pad and to the multi-layer interconnect pillar.

25. The device of claim 23, further comprising a barrier layer coupled to and disposed between the solder cap and the multi-layer interconnect pillar.

26. The device of claim 25, wherein a material of the solder cap forms Intermetallic compounds (IMCs) with a material of the barrier layer at a first rate, wherein the material of the solder cap forms IMCs with a material of the cap reinforcement layer at a second rate, and wherein the first rate is greater than the second rate.

27. The device of claim 25, wherein the barrier layer comprises copper.

28. The device of claim 23, wherein the multi-layer interconnect pillar further comprises:
one or more intermediate reinforcement layers disposed between the cap reinforcement layer and the base reinforcement layer; and
one or more additional solder layers, wherein solder layers and reinforcement layers alternate in the multi-layer interconnect pillar.

29. The device of claim 23, wherein the multi-layer interconnect pillar further comprises a copper pillar between the base reinforcement layer and the contact pad.

30. The device of claim 23, wherein the cap reinforcement layer and the base reinforcement layer comprise nickel, cobalt, or both.
